(19) United States
(12) Patent Application Publication
(10) Pub. No.: US 2016/0266964 A1
(43) Pub. Date: Sep. 15, 2016

(54) PROGRAMMABLE LOGIC CIRCUIT DEVICE AND ERROR DETECTION METHOD THEREFOR

(71) Applicant: FUJITSU LIMITED, Kawasaki-shi (JP)

(72) Inventor: Shinichiro Uekusa, Kawasaki (JP)

(73) Assignee: FUJITSU LIMITED, Kawasaki-shi (JP)

(21) Appl. No.: 15/059,355

(22) Filed: Mar. 3, 2016

(30) Foreign Application Priority Data
Mar. 9, 2015 (JP) 2015-045804

(51) Int. Cl. G06F 11/10; G11C 7/00; G11C 29/44

(52) U.S. Cl. CPC G06F 11/1004; G11C 29/44; G11C 7/00

(57) ABSTRACT

A programmable logic circuit device has a configuration memory that stores configuration data; a programmable logic circuit in which a logic circuit is configured based on the configuration data stored in the configuration memory; a control circuit that sequentially and repeatedly reads, from the configuration memory, target configuration data corresponding to an error-check-target circuit in the programmable logic circuit, from among the configuration data in the configuration memory and; and an error detection circuit that executes an error check on the target configuration data read by the control circuit.

### CROSS-REFERENCE TO RELATED APPLICATION

This application is based upon and claims the benefit of priority of the prior Japanese Patent Application No. 2015-045804, filed on Mar. 9, 2015, the entire contents of which are incorporated herein by reference.

### FIELD

The present invention relates to a programmable logic circuit device and an error detection method therefor.

### BACKGROUND

A programmable logic circuit device (or a programmable logic device) is an integrated circuit device that allows an internal logic circuit to be modified after the LSI is manufactured. Among the programmable logic circuits, field programmable gate arrays (hereinafter referred to as FPGAs) enable data in an internal logic circuit to be rewritten.

Therefore, a user may download configuration data that defines the configuration of the internal logic circuit, into the FPGA at a desired timing to modify the FPGA into a desired logic circuit. For example, a communication integrated circuit device needs to be compatible with a change in communication standards, and thus, the FPGA is widely utilized. That is, the user modifies the configuration data for the manufactured FPGA in association with the new standards to enable the FPGA to be modified into an integrated circuit device corresponding to the new standards.

The FPGA has a built-in internal configuration memory that enables configuration data to be rewritten. The FPGA downloads configuration data in an external memory into an internal configuration memory. As a result, the internal logic circuit is reconfigured based on the configuration data written to the configuration memory.

The recently reduced size and increased scale of the FPGA cause a soft error in which the configuration data written to the internal configuration memory is subjected to bit inversion due to radiation. Thus, the FPGA constantly reads the configuration data in the configuration memory to check for an error, and if a detected error is correctable, generates and writes corrected configuration data over the configuration data in the configuration memory. When an error is detected as a result of the error check, the FPGA reports the error detection to a higher system. In response, the higher system discards the results of the corresponding process executed by the internal logic circuit because the results include an error. The higher system re-downloads the configuration data into the configuration memory and allows re-execution of the process in which the error has occurred.

The soft error in the FPGA is described in Japanese Patent Application Laid-open No. 2006-344223, Japanese Patent Application Laid-open No. 2007-293856, and Japanese PCT National Publication No. 2014-502452.

### SUMMARY

The FPGA sequentially reads the configuration data in the configuration memory and repeats the error check. Thus, a time delay occurs after a soft error occurs in certain configuration data and before the error is detected.

The internal logic circuit in which the soft error has occurred is configured using the error data. Thus, outputs from the logic circuit are unreliable. Therefore, the time between the occurrence of a soft error and the detection of the error is desirably minimized as much as possible.

One aspect of the present disclosure is a programmable logic circuit device has a configuration memory that stores configuration data; a programmable logic circuit in which a logic circuit is configured based on the configuration data stored in the configuration memory; a control circuit that sequentially and repeatedly reads, from the configuration memory, target configuration data corresponding to an error-check-target circuit in the programmable logic circuit, from among the configuration data in the configuration memory and; and an error detection circuit that executes an error check on the target configuration data read by the control circuit.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram depicting a configuration of a programmable logic circuit device;

FIG. 2 is a diagram depicting an example of a bit map for the configuration memory 12;

FIG. 3 is a diagram depicting an example of a configuration of the programmable logic circuit 11;

FIG. 4 is a diagram depicting an example of a configuration of a lookup table;

FIG. 5 is a diagram depicting an example of a configuration of the configuration memory in the programmable logic circuit device;

FIG. 6 is a flowchart of an example of error detection performed by the CRAM control circuit and the error detection and correction circuit;

FIG. 7 is a timing chart illustrating an example of an operation of detecting an error in configuration data performed by the CRAM control circuit and the error detection and correction circuit;

FIG. 8 is a diagram depicting an example of a configuration of the programmable logic circuit device in the first embodiment;

FIG. 9 is a diagram depicting a circuit configuration of the CRAM control circuit 13 in the first embodiment;

FIG. 10 is a flowchart of an example of the error detection operation performed by the CRAM control circuit and the error detection and correction circuit in the first embodiment;

FIG. 11 is a timing chart illustrating an example of the operation of detecting an error in configuration data performed by the CRAM control circuit and the error detection and correction circuit in the present embodiment;

FIG. 12 is a table illustrating priority values for the error check for a soft error;

FIG. 13 is a diagram depicting an example of the programmable logic circuit;

FIG. 14 is a diagram depicting an example of design data on a programmable logic circuit generated using a design tool;

FIG. 15 is a diagram illustrating an example of the priority values of the error check for the circuit blocks and the frame addresses in the programmable logic circuit device in FIGS. 13 and 14;

FIG. 16 is a diagram illustrating an example of the error check priority value and the next frame address for each frame address generated by the design tool based on FIG. 15;

FIG. 17 is a diagram depicting a variation of the first embodiment;

FIG. 18 is a diagram depicting an example of a configuration of a programmable logic circuit device in the second embodiment; and

FIG. 19 is a diagram depicting an example of a configuration of a programmable logic circuit device in a variation of the second embodiment.

### DESCRIPTION OF EMBODIMENTS

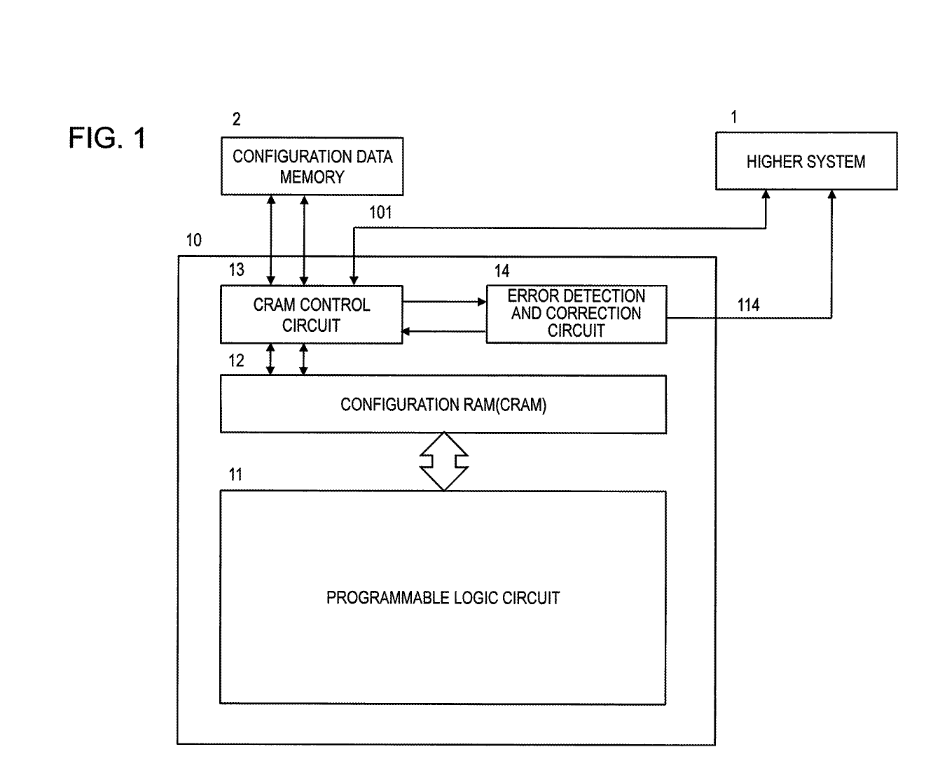

FIG. 1 is a diagram depicting a configuration of a programmable logic circuit device. The programmable logic circuit device is, for example, an FPGA. An FPGA 10 has a configuration memory (CRAM: Configuration RAM) 12 that stores configuration data, and a programmable logic circuit 11 in which a logic circuit is configured based on the configuration data stored in the configuration memory. The FPGA 10 also has a CRAM control circuit 13 that controls writing and reading of data to and from the configuration memory 12 and an error detection and correction circuit 14 that executes an error check on the configuration data, and if a detected error is correctable, corrects the configuration data including the error.

The FPGA 10 is connected to an external configuration data memory (second configuration memory) 2 with configuration data written thereto. The external configuration data memory 2 is a nonvolatile memory, for example, a flash memory.

When a circuit is designed using a design tool, configuration data corresponding to the designed logic circuit is generated. Then, the configuration data and codes for error detection and correction for the configuration data are stored in the external configuration data memory 2. The external configuration data memory 2 does not substantially suffer inversion of values of stored data caused by radiation or is more unlikely to suffer the inversion than the configuration memory 12. Therefore, the external configuration data memory 2 stores almost always correct configuration data and codes for error detection and correction.

In response to a download instruction signal 101 from a higher system 1, the CRAM control circuit 13 downloads the configuration data from the external configuration data memory 2 and writes the configuration data to the internal configuration memory 12. The higher system 1 generates the download instruction signal 101, for example, when the programmable logic circuit device is powered on or when an uncorrectable error occurs in the configuration data in the programmable logic circuit.

When configuration data is written to the configuration memory 12, the programmable logic circuit 11 is reconfigured based on the configuration data.

The configuration memory 12 is, for example, a SRAM (Static RAM). The configuration memory 12 stores a large capacity of configuration data but suffers a soft error in which the values of stored configuration data are inverted due to radiation such as neutrons. The values of data may be inverted by any other factor other than the radiation, for example, a variation in power supply.

In the programmable logic circuit 11, a logic circuit configuration is set based on the configuration data as described below. Thus, inverted values of the configuration data change the function of the logic circuit.

Thus, the CRAM control circuit 13 reads the configuration data in the configuration memory 12 and supplies the data to the error detection and correction circuit 14. In response, the error detection and correction circuit 14 checks whether the configuration data includes an error. Upon detecting an error, the error detection and correction circuit 14 corrects the error if possible, and writes the corrected configuration data over the configuration data in the configuration memory 12 via the CRAM control circuit 13. The error detection and correction circuit 14 then transmits an error notification 114 including a configuration with the error having occurred therein and whether or not a correction has been executed, to the higher system 1.

Occurrence of a soft error is unpredictable, and thus, the CRAM control circuit 13 constantly repeatedly reads the configuration data in the configuration memory 12 in order and allows the error detection and correction circuit 14 to execute an error check.

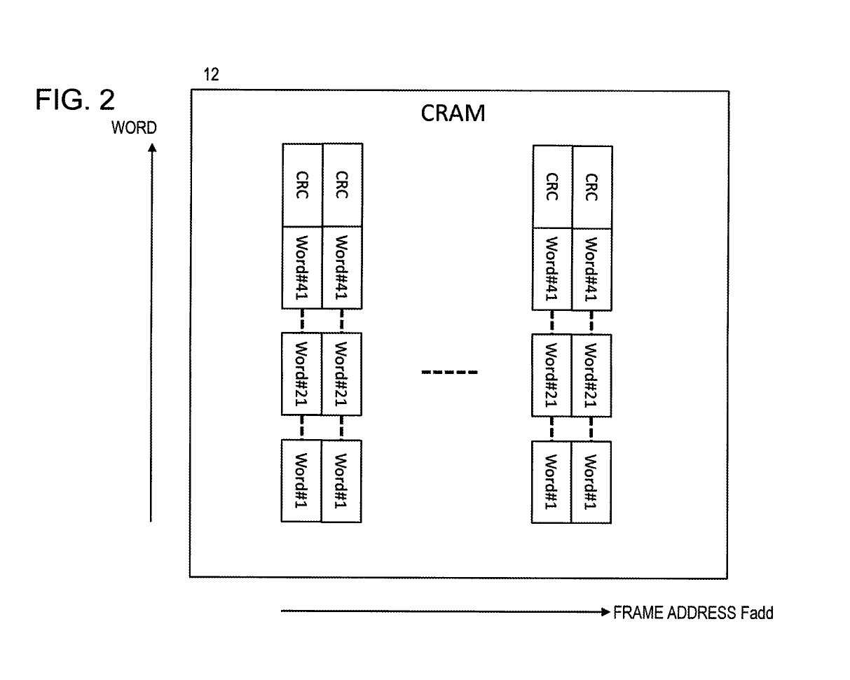

FIG. 2 is a diagram depicting an example of a bit map for the configuration memory 12. The configuration memory 12 stores 41 word data and CRC (Cyclic Redundancy Check) codes for each lateral frame address Fadd. One word is, for example, 32 bits. An ECC (Error Correcting Code) is stored in one of the 41 words (for example, a word #21) of one frame address.

The configuration data in the 40 words in each frame address are subjected to error checks by the CRC codes pre-calculated by the design tool and to error corrections by the ECC. Thus, when a soft error occurs in the configuration data in each frame address, the error detection and correction circuit 14 detects the error, and if possible, corrects the error to generate corrected configuration data.

To access the configuration memory 12, the CRAM control circuit 13 reads or writes the CRC codes and the 41 word data based on the frame address Fadd. Therefore, to read all of the configuration data in the configuration memory 12, the CRAM control circuit 13 has to repeat an operation of reading the configuration data for all of the frame addresses.

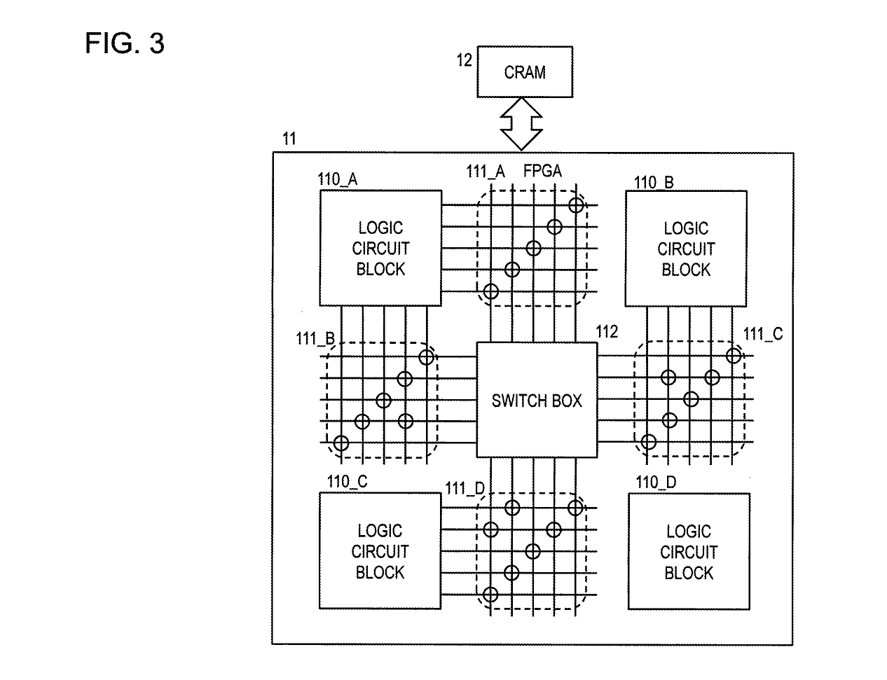

FIG. 3 is a diagram depicting an example of a configuration of the programmable logic circuit 11. The programmable logic circuit 11 has a plurality of logic circuit blocks 110_A to 110_D, a switch box 112 that connects wires together, and connection blocks 111-A to 111-D that connects the wires and I/O terminals of the logic circuit blocks 110. Each of the logic circuit blocks 110 has a logic circuit and a lookup table described below. Configuration data is stored in the lookup table as reference data. The switch box 112 has a plurality of switches not depicted in the drawings. Any of the switches are configured to be in an on state or off state based on the configuration data. Each of the connection blocks 111 has switches located at the respective intersection positions between the wires and the I/O terminal wires of the logic circuit block. The switches are configured to be in the on state or off state based on the configuration data.

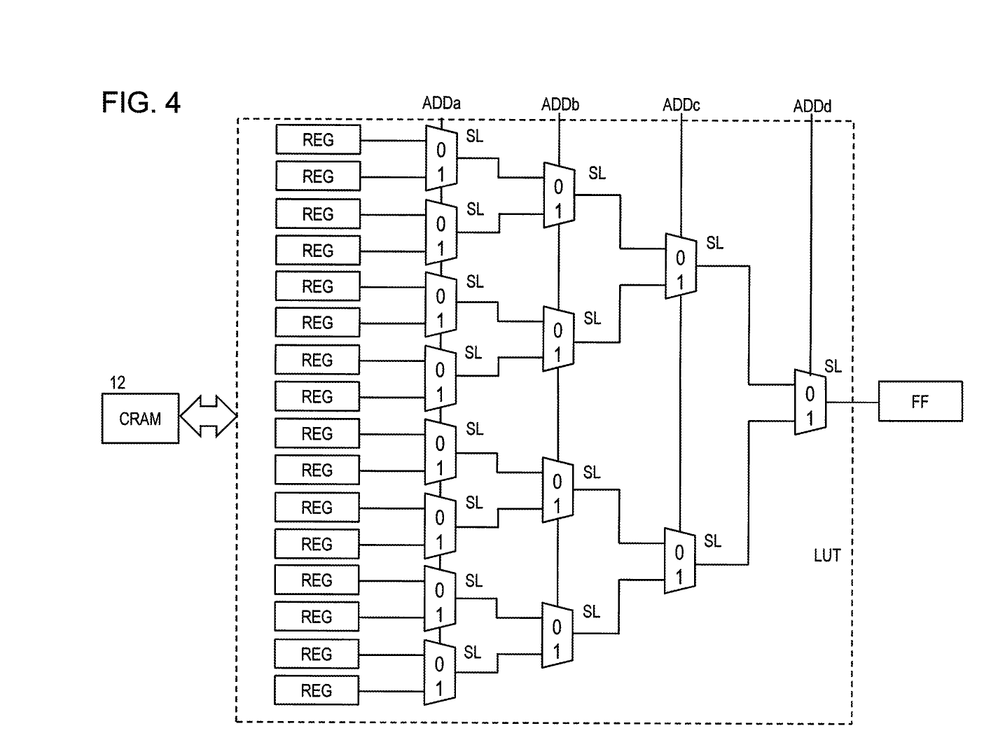

FIG. 4 is a diagram depicting an example of a configuration of a lookup table. A lookup table LUT is provided in the programmable logic circuit 11. The lookup table LUT has a plurality of registers REG and a plurality of selectors SL arranged in a tournament form to select one of the registers REG. The configuration data in the configuration memory 12 are stored in the registers REG. The selectors SL are controlled using addresses ADDa to ADDd in the lookup table LUT. In an example in FIG. 4, the lookup table LUT has 16 registers REG and 15 selectors SL.

Any lookup table can be configured by storing the configuration data in the registers REG in the lookup table LUT. The lookup table LUT outputs data in the register selected based on the addresses ADDa to ADDd generated by the logic circuits and the like. The data is latched by a flip flop FF connected to an output.

As understood from FIG. 3 and FIG. 4, in the programmable logic circuit 11, the group of switches and the lookup table are configured into any states based on the configuration data to form any logic circuit. When a soft error occurs in the configuration data in the configuration memory 12, the functions of the configured logic circuit are changed to prevent the logic circuit from operating correctly.

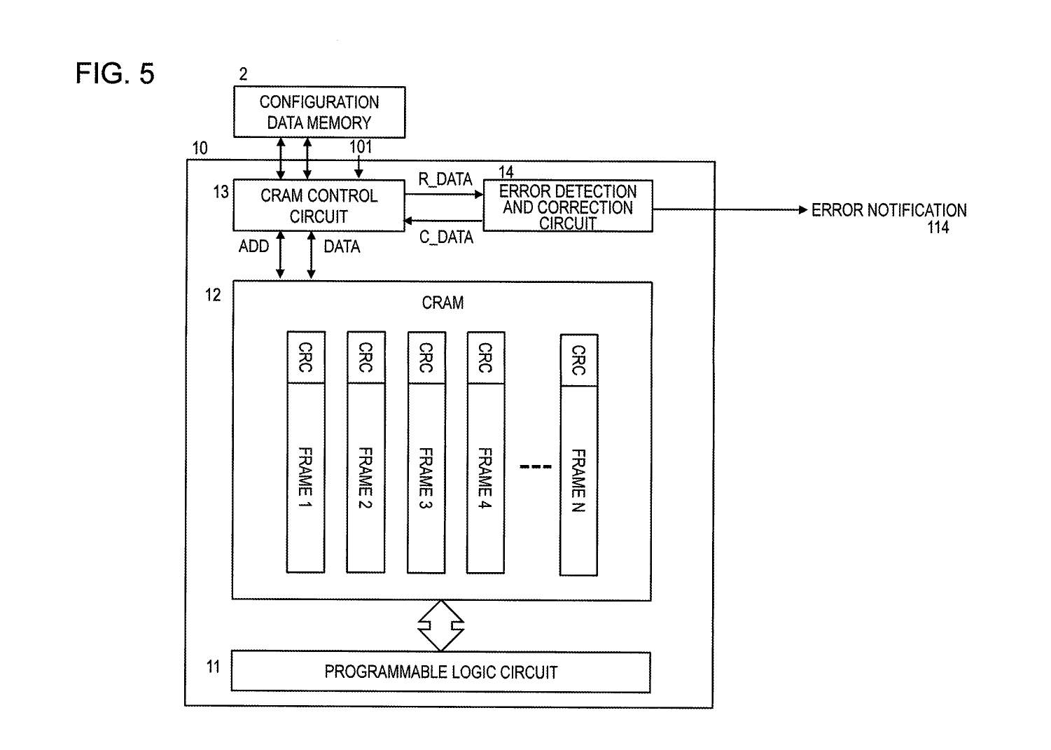

FIG. 5 is a diagram depicting an example of a configuration of the configuration memory in the programmable logic circuit device. As described with reference to FIG. 2, the configuration memory 12 stores configuration data of a predetermined number of bits and CRC codes therefor for every plurality of frame addresses. The configuration data may suffer a soft error in which the values of the data are inverted due to radiation or the like.

The CRAM control circuit 13 reads the configuration data at each frame address in the configuration memory 12. The error detection and correction circuit 14 then executes an error check on the read configuration data, and if a detected error is correctable, generates and overwrites the configuration memory 12 with corrected configuration data with the error corrected. The read of the configuration data, the error check and correction, and the overwrite of the corrected configuration data are cyclically repeated for all of the frame addresses.

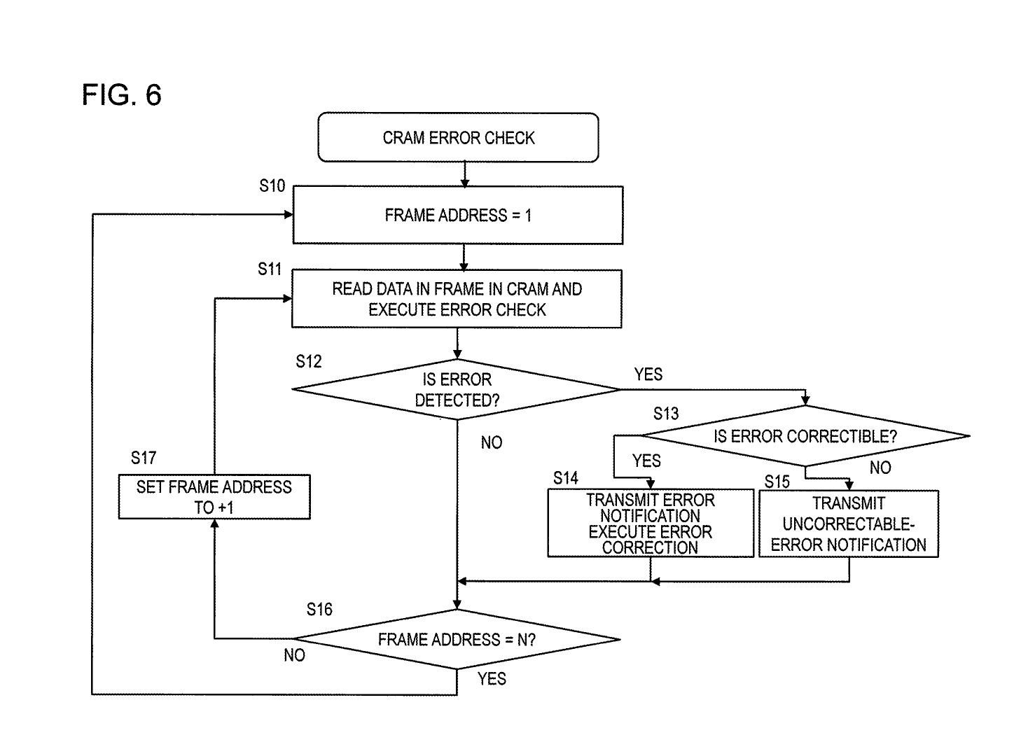

FIG. 6 is a flowchart of an example of error detection performed by the CRAM control circuit and the error detection and correction circuit. The CRAM control circuit 13 sets the frame address to 1 (S10), and accesses the configuration memory 12 to read configuration data and ECCs and CRC codes therefor at a frame address Fadd=1 in the configuration memory 12. The CRAM control circuit 13 then supplies the read data R_DATA to the error detection and correction circuit 14.

The error detection and correction circuit 14 calculates CRC codes from the read configuration data and compares the CRC codes with pre-stored CRC codes to check whether or not the read configuration data includes an error (S11). When the comparison results in a mismatch indicating that an error has been detected (S12, YES), if the error is correctable (S13, YES), the error detection and correction circuit 14 executes an error correction based on the ECCs and transmits an error notification 114 to the higher system (S14). If the error is uncorrectable (S13, NO), the error detection and correction circuit 14 transmits an error notification 114 indicating that the error is uncorrectable to the higher system (S15). Each of the error notifications 114 includes information indicating at which of the frame addresses the soft error has occurred. The error detection and correction circuit 14 returns corrected configuration data C_DATA to the CRAM control circuit 13. The CRAM control circuit 13 overwrites the configuration memory with the corrected configuration data.

The CRAM control circuit 13 increments the frame address by +1 (S17) until the frame address reaches the last address N (S16, NO). The following are then repeated: the operation of reading the configuration data, the error detection and correction performed by the error detection and correction circuit 14, and the operation of writing the corrected configuration data.

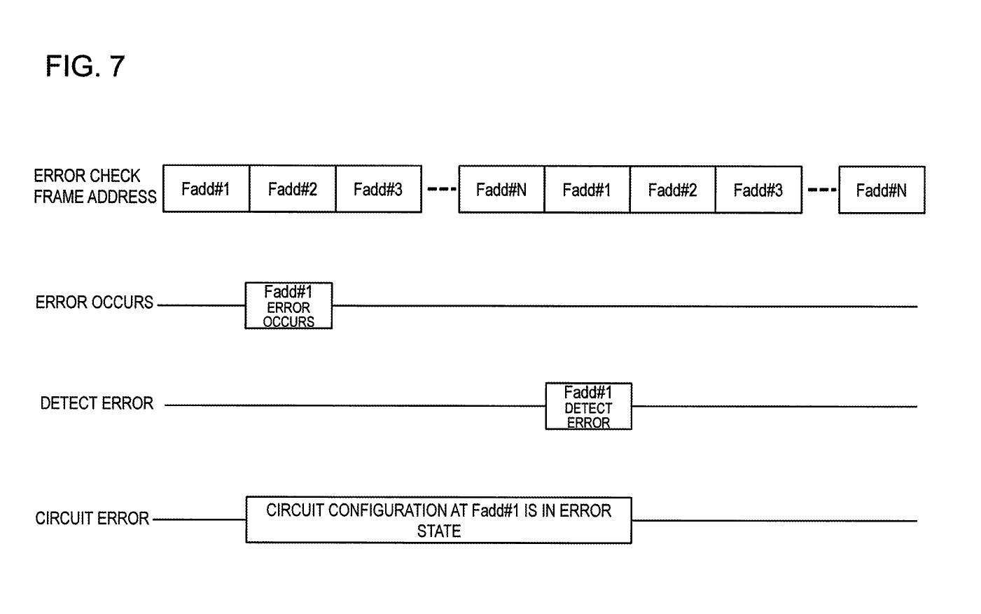

FIG. 7 is a timing chart illustrating an example of an operation of detecting an error in configuration data performed by the CRAM control circuit and the error detection and correction circuit. The CRAM control circuit 13 accesses the configuration memory at each frame address while sequentially and cyclically changing the error-check-target frame address from Fadd#1 to Fadd#N to read the configuration data and the CRC codes and the ECCs therefor at each frame address. The error detection and correction circuit 14 then executes an error check and an error correction on the read configuration data.

In an example in FIG. 7, immediately after an error check on the frame address Fadd#1 ends, a soft error occurs in the configuration data at the frame address Fadd#1 while an error check is being executed on the configuration data at the frame address Fadd#2. In that case, the CRAM control circuit 13 does not detect the error until the CRAM control circuit 13 executes an error check on the configuration data at the frame address Fadd#1. As a result, the functions of the programmable logic circuit remain incorrect during the period of the error check operation for one cycle for the frame address Fadd from occurrence to detection of an error, in the worst case.

When the functions of the logic circuit are made incorrect, the configuration data with the error detected therein needs to be corrected and the configuration memory needs to be overwritten with the corrected configuration data to reset the configuration of the programmable logic circuit. Therefore, the period of an error state (failure state) from occurrence to detection of the error in the configuration data needs to be minimized.

An error detection period increases consistently with a configuration data capacity based on the circuit scale of the programmable logic circuit. Therefore, the error time from occurrence to detection of the error increases consistently with the circuit scale, and this is not preferable.

### First Embodiment

In the programmable logic circuit device, not all of the programmable logic circuits are configured using effective configuration data. For example, an example of a designed FPGA, there is a report that approximately 50% of the frames of the configuration data is used when the usage rate of the programmable logic circuit is approximately 70%. In this case, error checks are needed for 50% of the frames.

A part of a logic circuit configured using effective configuration data may have a function to detect a functional failure using another means or have a redundant configuration to allow, when a failure occurs, a failing circuit to be switched to another redundant circuit. Error checks need not constantly be executed on such a logic circuit. For such a logic circuit, the periods of constantly repeated error check operations can be shortened by omitting the error checks executed by the error detection and correction circuit, and allowing the error detection and correction circuit to execute an error check and an error correction if an error is detected by another means.

The time needed for a read operation for the configuration memory during the error detection operation is relatively long compared to the time needed for the error check and correction executed by the error detection and correction circuit 14. Therefore, the period of the error check can be substantially shortened by reducing the number of operations of reading configuration data that does not need an error check from the configuration memory.

Thus, in the programmable logic circuit device in the first embodiment, the CRAM control circuit 13 repeatedly and sequentially reads target configuration data corresponding to an error check target circuit in programmable logic circuit 11, from among the entire configuration data in the configuration memory 12. The error detection circuit executes an error check on the target configuration data read by the CRAM control circuit 13.

In other words, instead of reading sequentially all of the data in the configuration memory 12 for error checks, the CRAM control circuit 13 and the error detection and correction circuit 14 sequentially and cyclically read only the target configuration data corresponding to the error check target circuit in the programmable logic circuit, for error checks. This operation reduces the period of the error check compared to the execution of the error check on all the data in the configuration memory, enabling a reduction in the period from occurrence to detection of an error.

Japanese Patent Application Laid-open No. 2006-344223 and Japanese Patent Application Laid-open No. 2007-293856 describe FPGAs having a function to ignore the detection of an error in unused configuration data. However, the error detection is performed on all of the configuration data.

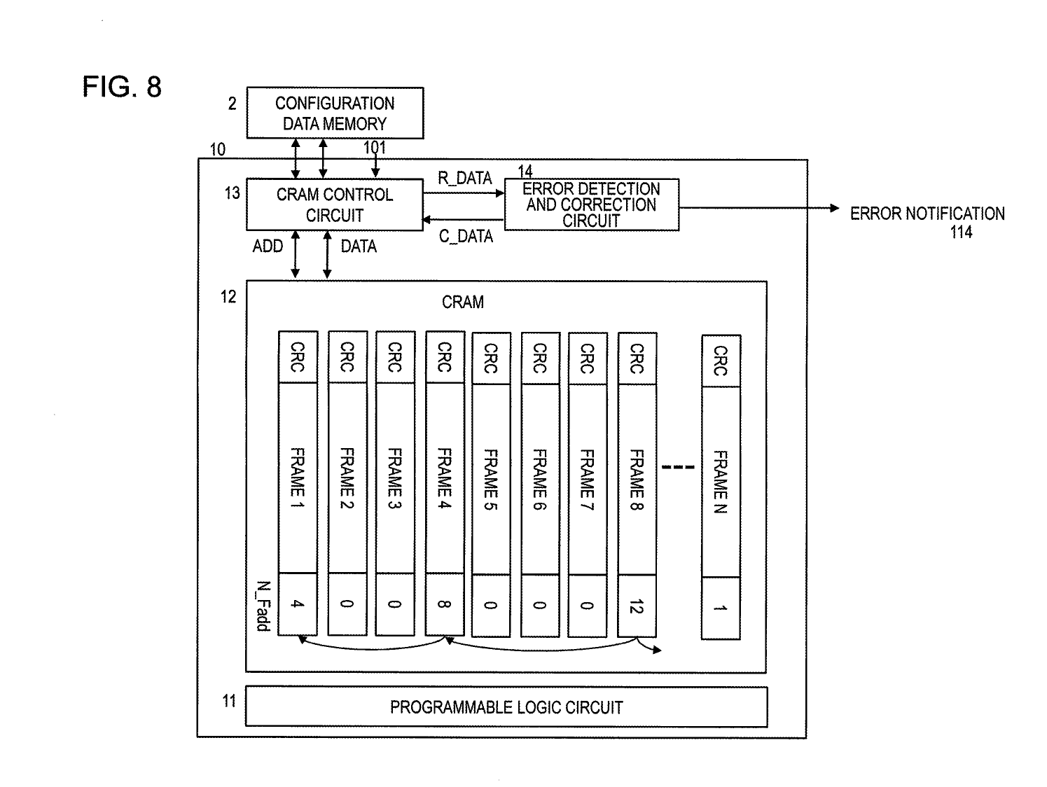

FIG. 8 is a diagram depicting an example of a configuration of the programmable logic circuit device in the first embodiment. The external configuration data memory 2 stores, in addition to configuration data and error check codes CRC, the addresses of target configuration data corresponding to an error-check-target logic circuit. In other words, at a design stage of the programmable logic circuit, the addresses of the target configuration data corresponding to the error-check-target logic circuit are generated using the design tool and stored in the external configuration data memory 2.

In response to the download instruction signal 101 supplied by the higher system 1 when the device is powered on or when an error is detected, the CRAM control circuit 13 downloads the data in the external configuration data memory 2 into the internal configuration memory 12.

FIG. 8 depicts a configuration of the data downloaded into the configuration memory 12. The configuration memory 12 stores configuration data and the error detection code CRC at each frame address. In the first embodiment, the configuration memory 12 stores, in addition to the configuration data, the frame addresses of the target configuration data corresponding to the error-check-target circuit. In particular, in the preferred embodiment, the next frame address to be subjected to an error check (the next frame address N_Fadd) is stored at each frame address, in addition to the configuration data and the error detection code CRC.

In an example in FIG. 8, frames 1, 4, 8, 12, and N store the target configuration data. Therefore, the next frame address N_Fadd=4 is stored in the frame 1, the next frame address N_Fadd=8 is stored in the frame 4, the next frame address N_Fadd=12 is stored in the frame 8, and the next frame address N_Fadd=1 is stored in the frame N.

In such a configuration, the configuration data is stored in the configuration memory 12 to allow the CRAM control circuit 13 to sequentially read only the frames with the target configuration data stored therein during the error check operation.

Even when the frame 1 stores no target configuration data, the next frame address N_Fadd in the frame 1 is read, allowing only the error-check-target configuration data to be read during the subsequent read operations. Instead of the frame address of the frame 1, the frame address of the initial target configuration data is stored in the frame N to avoid reading the frame 1 in or after the next error check period.

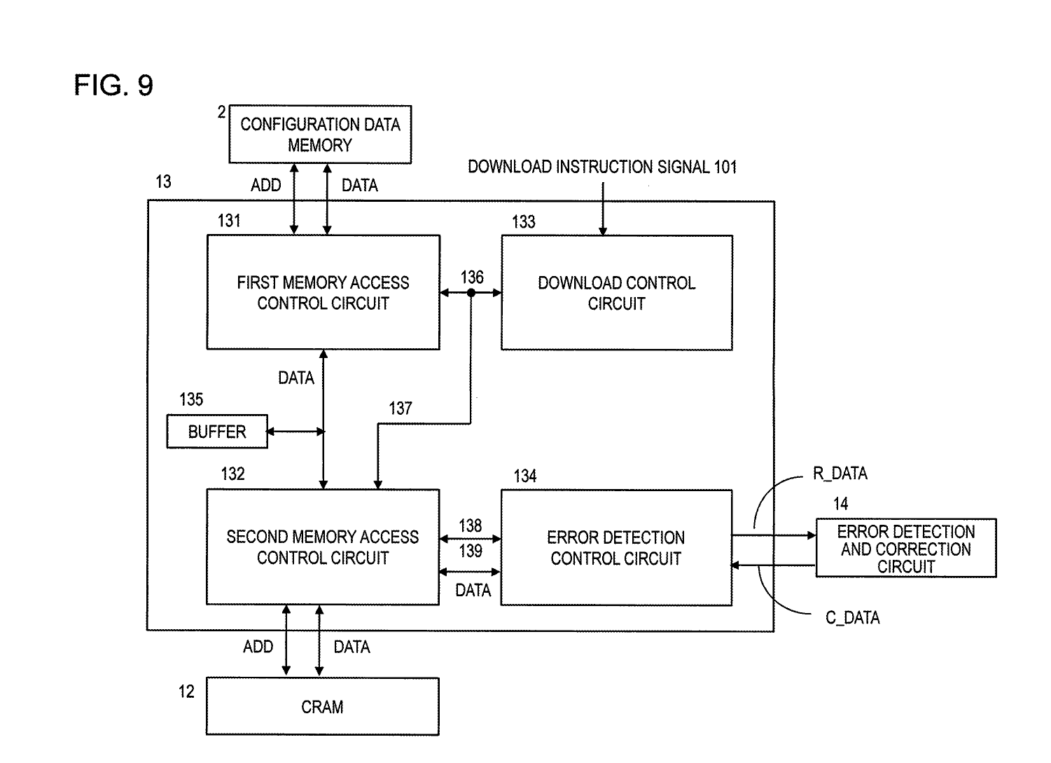

FIG. 9 is a diagram depicting a circuit configuration of the CRAM control circuit 13 in the first embodiment. The CRAM control circuit 13 has a first memory access control circuit 131 that controls memory accesses to the external configuration data memory 2 and a second memory access control circuit 132 that controls memory accesses to the internal configuration data memory 12.

The CRAM control circuit 13 further has a download control circuit 133 that controls downloading of data from the external configuration data memory 2 in response to the download instruction signal 101. The download control circuit 133 outputs a read instruction signal 136 for reading data in the external configuration data memory 2, to the first memory access control circuit 131. The download control circuit 133 also outputs a write instruction signal 137 for writing data in the internal configuration memory 12, to the second memory access control circuit 132. The configuration data read by the first memory access control circuit 131 may be temporarily stored in a data buffer 135. Then, the second memory access control circuit 132 writes the configuration data in the data buffer 135 to the internal configuration memory 12. The read and write of the configuration data are each sequentially performed for each frame address.

The CRAM control circuit 13 has an error detection control circuit 134 that controls error checks and error corrections. The error detection control circuit 134 outputs a read instruction signal 138 to the second memory access control circuit 132 to constantly and sequentially read the target configuration data in the internal configuration memory 12. The error detection control circuit 134 then outputs the read configuration data R_DATA to the error detection and correction circuit 14. The error detection control circuit 134 also outputs a write instruction signal 139 to the second memory access control circuit 132 to overwrite the configuration memory 12 with the corrected configuration data C_TADA with an error corrected by the error detection and correction circuit 14.

The error detection control circuit 134 initially reads the configuration data at the frame address Fadd=1 and extracts the next frame address N_Fadd from the frame address Fadd=1 and uses the next frame address N_Fadd as a frame address for the next read instruction signal 138.

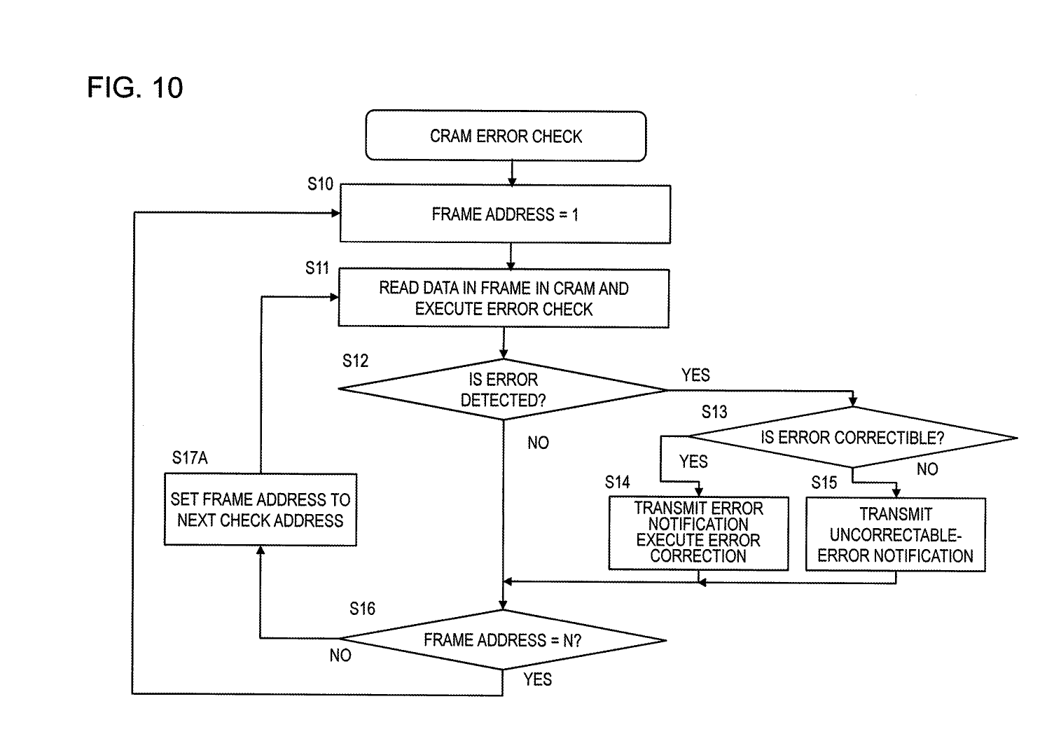

FIG. 10 is a flowchart of an example of the error detection operation performed by the CRAM control circuit and the error detection and correction circuit in the first embodiment. The error detection operation in FIG. 10 is different from the error detection operation in FIG. 6 in an operation of setting the next frame address in step S17A. That is, in step S17A, the CRAM control circuit 13 extracts the next frame address N_Fadd from the read frame and sets the next frame address N_Fadd to be the next frame address Fadd to be accessed.

First, the CRAM control circuit 13 sets the frame address to an initial value of 1 (S10) and accesses the configuration memory 12 to read the configuration data at the frame address Fadd=1 and the ECC and the CRC code therefor. The CRAM control circuit 13 then supplies the read data R_DATA to the error detection and correction circuit 14 (S11).

The error detection and correction circuit 14 calculates the CRC codes from the read configuration data and compares the CRC codes with pre-stored CRC codes to check whether or not the read configuration data includes an error (S11). When an error is detected (S12, YES), if the error is correctable (S13, YES), the error detection and correction circuit 14 executes an error correction based on the ECCs and transmits the error notification 114 to the higher system (S14). If the error is uncorrectable (S13, NO), the error detection and correction circuit 14 transmits the error notification 114 indicating that the error is uncorrectable to the higher system (S15). Each of the error notifications 114 includes information indicating at which of the frame addresses the soft error has occurred. The error detection and correction circuit 14 returns the corrected configuration data C_DATA to the CRAM control circuit 13. The CRAM control circuit 13 overwrites the configuration memory with the corrected configuration data. The above-described operation is similar to the corresponding operation in FIG. 6.

When the accessed frame address is not the final address N (S16, NO), the CRAM control circuit 13 extracts the next frame address N_Fadd in the read frame and sets the frame address N_Fadd to be the next frame address to be accessed (S17A). The followings are then repeated: the operation of reading the configuration data, the error detection and correction performed by the error detection and correction circuit 14, and the operation of writing the corrected configuration data.

As described above, the CRAM control circuit 13 reads only the target configuration data included in the entire data in the configuration memory 12 based on the frame addresses Fadd of the target configuration data stored in the configuration memory 12. The error detection and correction circuit 14 then executes an error check and also performs an error correction if possible and overwrites the internal configuration memory 12 with the corrected data.

In the example illustrated in FIG. 8, the next frame addresses N_Fadd in the configuration memory 12 are 4, 8, 12, N, and 1 (N is not depicted in FIG. 8). Thus, instead of reading the configuration data at all the frame addresses, the CRAM control circuit 13 reads the configuration data at the frame addresses Fadd=1, 4, 8, 12, and N only. Therefore, the CRAM control circuit 13 can reduce the error check period compared to the error check period achieved when all of the data in the configuration memory are read and subjected to error checks.

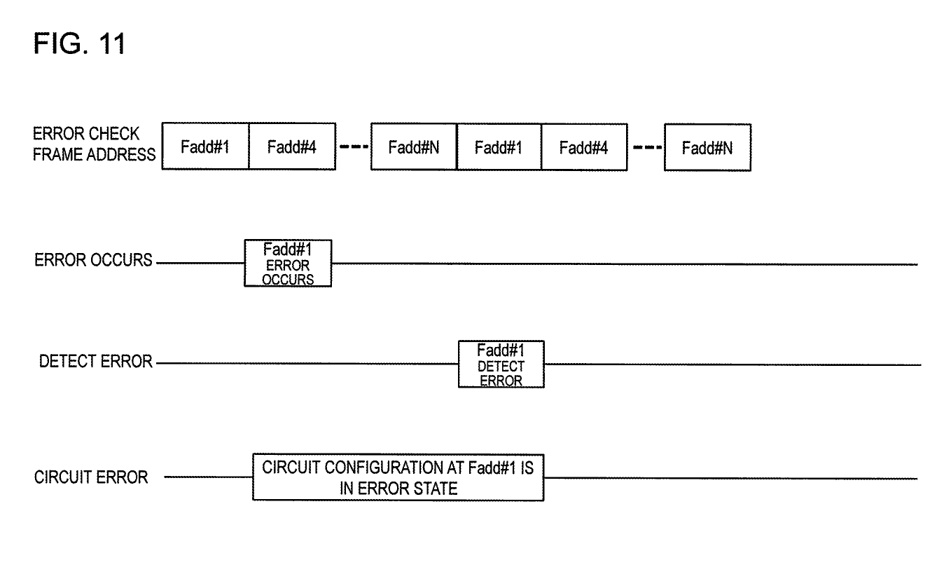

FIG. 11 is a timing chart illustrating an example of the operation of detecting an error in configuration data performed by the CRAM control circuit and the error detection and correction circuit in the present embodiment. The CRAM control circuit 13 initially sets the error-check-target frame address to be Fadd#1 and then accesses the configuration memory 12 while sequentially and cyclically changing the error-check-target frame address to the next frame address N_Fadd in the configuration memory 12, to read the configuration data and the CRC code and the ECC therefor at each frame address. The error detection and correction circuit 14 then executes an error check on the read configuration data.

In the example in FIG. 7, after the error check on the frame address Fadd#1 ends, a soft error occurs in the configuration data at the frame address Fadd#1 while the error detection operation is being performed on the configuration data at the frame address Fadd#2 succeeding the frame address Fadd#1. Therefore, it takes a long period until detecting the soft error. However, in an example in FIG. 11, the CRAM control circuit 13 accesses the frame addresses Fadd#4, Fadd#8, Fadd#12, and Fadd#N only. Then, the CRAM control circuit 13 detects an error when checking the configuration data at the frame address Fadd#1 during the next error check period. This reduces the amount of time from the occurrence of the error at the frame address Fadd#1 until the detection of the error at the frame address Fadd#1, compared to the case where the error check is executed at all the frame addresses. In other words, the period is reduced while the circuit configuration formed using the configuration data at the frame address Fadd#1 remains in the error state.

[Generation of the Frame Addresses of the Target Configuration Data]

Now, generation the frame addresses of the target configuration data will be described. First, the programmable logic circuit device such as an FPGA has a plurality of circuit blocks. The circuit blocks include a first circuit block in which the circuit configuration needs to be prevented from being changed by a soft error, a second circuit block with a self failure detection function to independently detect a failure in the circuit, and a third circuit block that has a redundant configuration such that, when the operation is determined to be abnormal, the circuit is switched to one with the redundant configuration to allow the operation to be continued. The priorities of a soft error check for the circuit blocks are as follows.

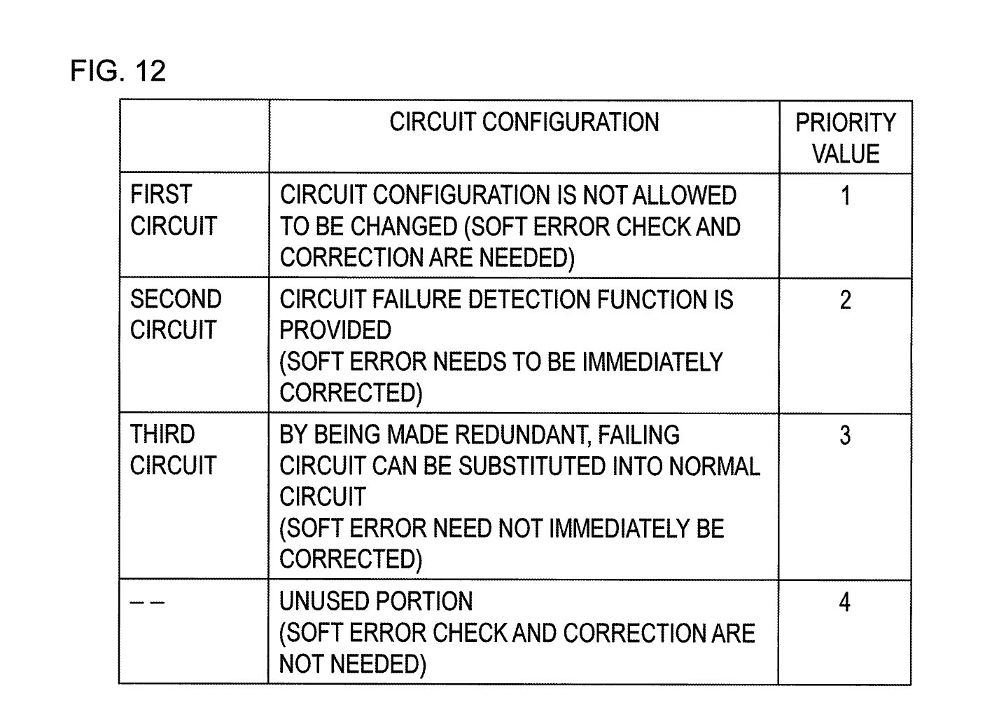

FIG. 12 is a table illustrating priority values for the error check for a soft error. In an example in FIG. 12, the priority increases with decreasing error check priority value.

The first circuit block needs constant error checks because a possible soft error makes the circuit operation abnormal. Thus, the error check priority value is desirably set to “1”, which is indicative of the highest priority.

The second circuit block has the self failure detection function and does not need constant error checks. However, when the self failure detection function detects a failure, if the failure is caused by a soft error, the configuration data is corrected and the configuration memory is overwritten with the corrected configuration data, or if the configuration data is uncorrectable, the configuration data is downloaded from the external configuration data memory 2. Therefore, the error check priority value is desirably set to “2”, which represents the second highest priority.

The third circuit block allows the operation to be continued for a while using the circuit with the redundant configuration even when a failure is detected. Thus, the error check and the error correction may be performed at predetermined timings. Therefore, the error check priority value is desirably set to “3”, which represents the next highest priority.

It should be noted that, in the programmable logic circuit device, not all the circuit configurations are configured into effective circuits based on effective configuration data. Therefore, the error check may be executed exclusively on the configuration data forming the effective circuits.

In the programmable logic circuit device as described above, the soft error check need not be executed on those of the configuration data which do not form effective circuit configurations among the configuration data in the configuration memory. Therefore, the error check priority value for such configuration data is set to “4”, which represents the lowest priority.

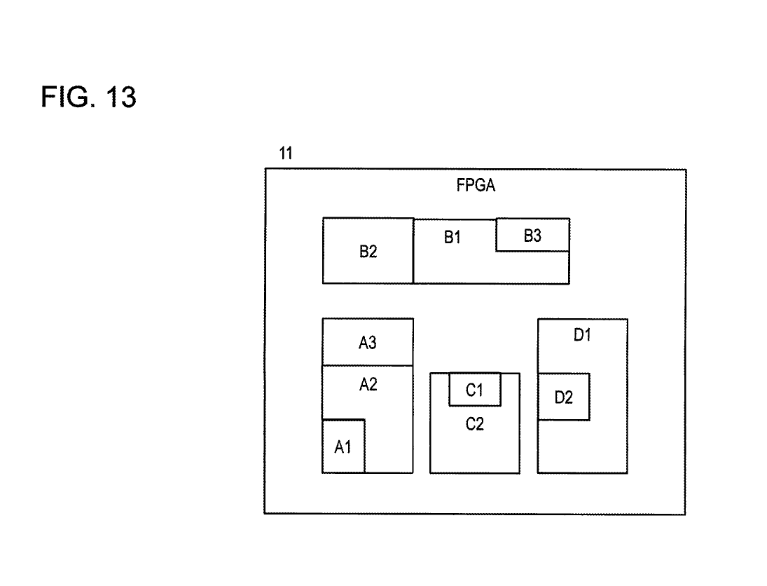

FIG. 13 is a diagram depicting an example of the programmable logic circuit. In an example in FIG. 13, circuit macros A, B, C, and D are configured. The circuit macro A has circuit blocks A1, A2, and A3. The circuit macro B has circuit blocks B1, B2, and B3. The circuit macro C has circuit blocks C1 and C2. The circuit macro D has circuit blocks D1 and D2.

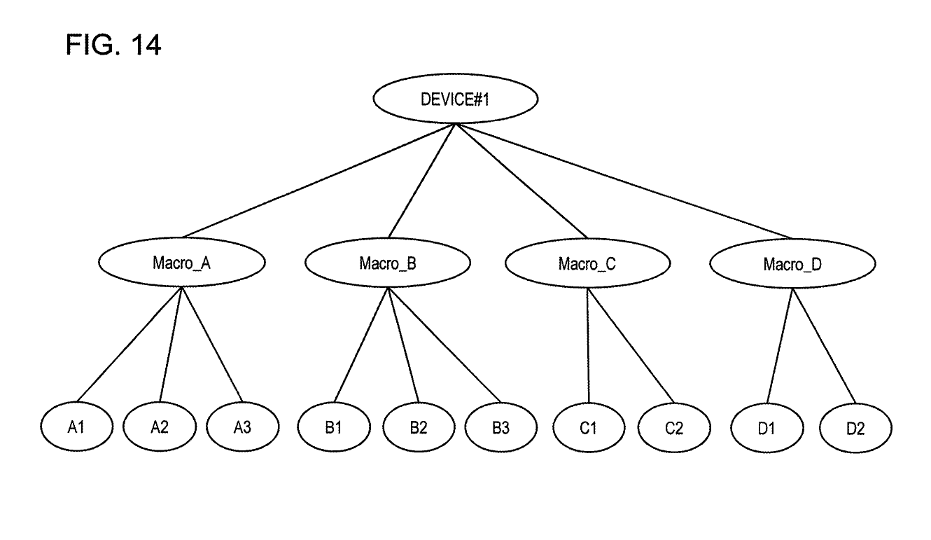

FIG. 14 is a diagram depicting an example of design data on a programmable logic circuit generated using a design tool. The design data in FIG. 14 corresponds to the example of the programmable logic circuit depicted in FIG. 13. That is, a programmable logic circuit device DEVICE#1 has the four circuit macros A, B, C, and D. The circuit macro A has the circuit blocks A1, A2, and A3, the circuit macro B has the circuit blocks B1, B2, and B3, the circuit macro C has circuit blocks C1 and C2, and the circuit macro D has circuit blocks D1 and D2, as is the case with FIG. 12.

The design tool that designs the programmable logic circuit device such as an FPGA generates configuration data that allows a logic circuit to be configured when the user arranges the circuit blocks and connects circuits together with wires. When generating the configuration data, the design tool generates error-check-target frame addresses to be stored in the configuration memory 12 with reference to the following information.

(1) Which of the configuration data is used to configure the LUT in the logic circuit block 110, the switch box 112 that connects the wires together, and the connection block 111 that connects the I/O terminals of the logic circuit block and the wires together.

(2) At which of the frame addresses the configuration data corresponding to each of the circuit blocks of a user circuit is stored.

(3) The priority value of the error check for a soft error for each of the circuit blocks of the user circuit.

As depicted in FIG. 8, the design tool adds the error-check-target frame address to the configuration data in each frame as the next check-target frame address N_Fadd. Desirably, the next check-target frame address N_Fadd is added to the configuration data so as to be arranged at the leading bit of each frame or a predetermined bit position.

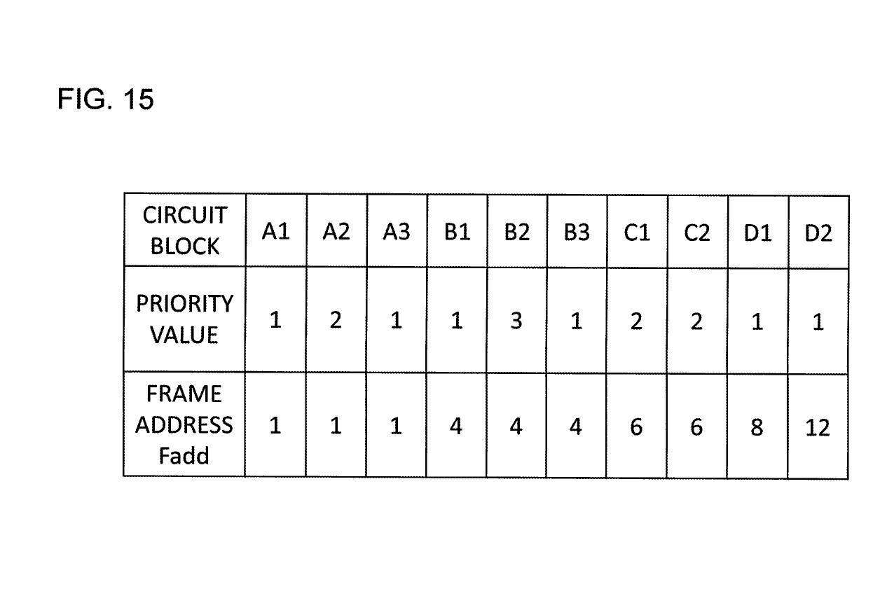

FIG. 15 is a diagram illustrating an example of the priority values of the error check for the circuit blocks and the frame addresses in the programmable logic circuit device in FIGS. 13 and 14. The design tool recognizes the error check priority values and the frame addresses corresponding to the 10 circuit blocks as depicted in FIG. 15 based on the above-described three pieces of information. FIG. 15 depicts the error check priority values and the frame addresses for all the designed circuit blocks. Therefore, configuration data at frame addresses absent from FIG. 15 do not form effective circuit blocks.

The design tool detects error-check-target frame addresses based on the data for the circuit blocks in FIG. 15. In that case, the error check is executed in accordance with the error check priority value, and thus, the error-check-target frame address is detected in accordance with the error check priority value. For example, for an error check priority value of “1”, the error-check-target circuit block is the circuit block with an error check priority value of “1”. For an error check priority value of “2”, the error-check-target circuit block is the circuit block with an error check priority value of “2” and “1”.

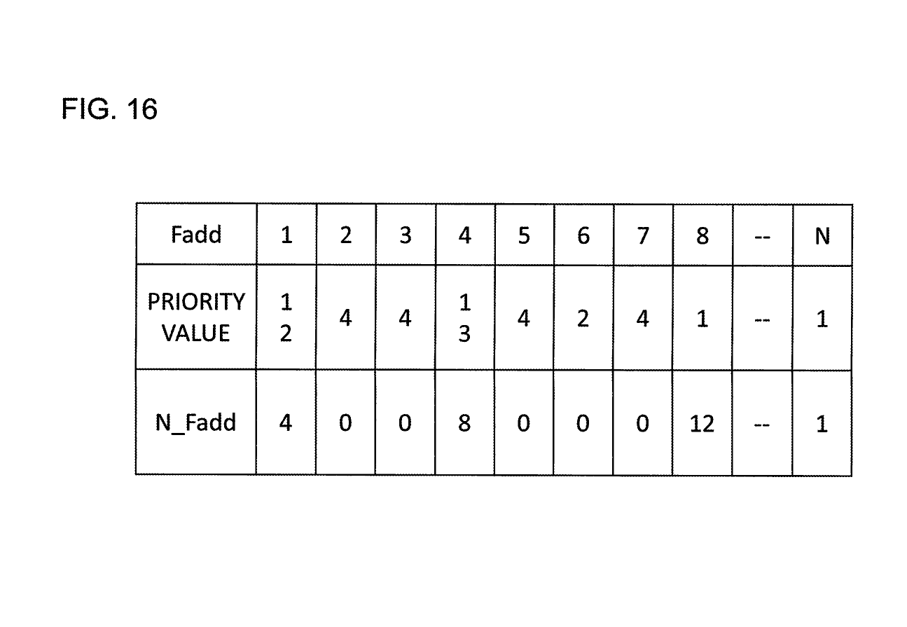

FIG. 16 is a diagram illustrating an example of the error check priority value and the next frame address for each frame address generated by the design tool based on FIG. 15. An example in FIG. 16 is an example where the next frame address N_Fadd indicates the address of a frame having a circuit block with an error check priority value of “1”. When configuration data for a plurality of circuit blocks is written to one frame and the plurality of circuit blocks has different error check priority values, the priority value of the highest priority (the smallest value) is set to be the error check priority value of the frame. Examples include frame addresses Fadd=1 and Fadd=4.

As is apparent from FIG. 15 and FIG. 16, the configuration data for the circuit blocks A1, A2, and A3 are written to the frame address Fadd=1. The circuit blocks A1, A2, and A3 have an error check priority value of “1” or “2”. The next frame address N_Fadd to be subjected to the error check is “4”. The configuration data for the circuit blocks B1, B2, and B3 are written to the frame address Fadd=4. The circuit blocks B1, B2, and B3 have an error check priority value of “1” or “3”. The next frame address N_Fadd is “8”. The configuration data for the circuit blocks C1 and C2 are written to the frame address Fadd=6. The circuit blocks C1 and C2 have an error check priority value of “2”. Therefore, the frame address Fadd=6 is not an error check target. The configuration data for the circuit blocks D1 and D2 are written to the frame addresses Fadd=8 and Fadd=12, respectively. The circuit blocks D1 and D2 have a priority value of “1”. In FIG. 16, configuration data for a circuit block not depicted in the drawings is written to the frame address Fadd=N. The circuit block has a priority value of “1”.

As depicted in FIG. 16, no configuration data for an effective circuit block is written to the frame addresses Fadd=2, Fadd=3, Fadd=5, and Fadd=7. Thus, the priority value in this case is “4”, which is indicative of the non-need of the error check.

When the priority value for error check targets is set to “1”, the error check targets are the frame addresses Fadd=1, Fadd=4, Fadd=8, Fadd=12, and Fadd=N. Thus, the error-check-target frame addresses N_Fadd in the frame addresses Fadd=1, Fadd=4, Fadd=8, Fadd=12, and Fadd=N are 4, 8, 12, N, and 1. As a result, 4, 8, 12, N, and 1 are written to the frames with frame address Fadd of 1, 4, 8, 12, and N (Fadd=12 is not depicted in the drawings) as the next frame addresses N_Fadd as depicted in the configuration memory 12 in FIG. 8.

### Variation of the First Embodiment

In the example in FIG. 8, the error-check-target frame addresses are written into each frame as the next frame addresses to be checked N_Fadd, and the error detection control circuit 134 extracts the next frame address N_Fadd from the configuration data in the read frame and utilizes the next frame address N_Fadd for read control for the next frame.

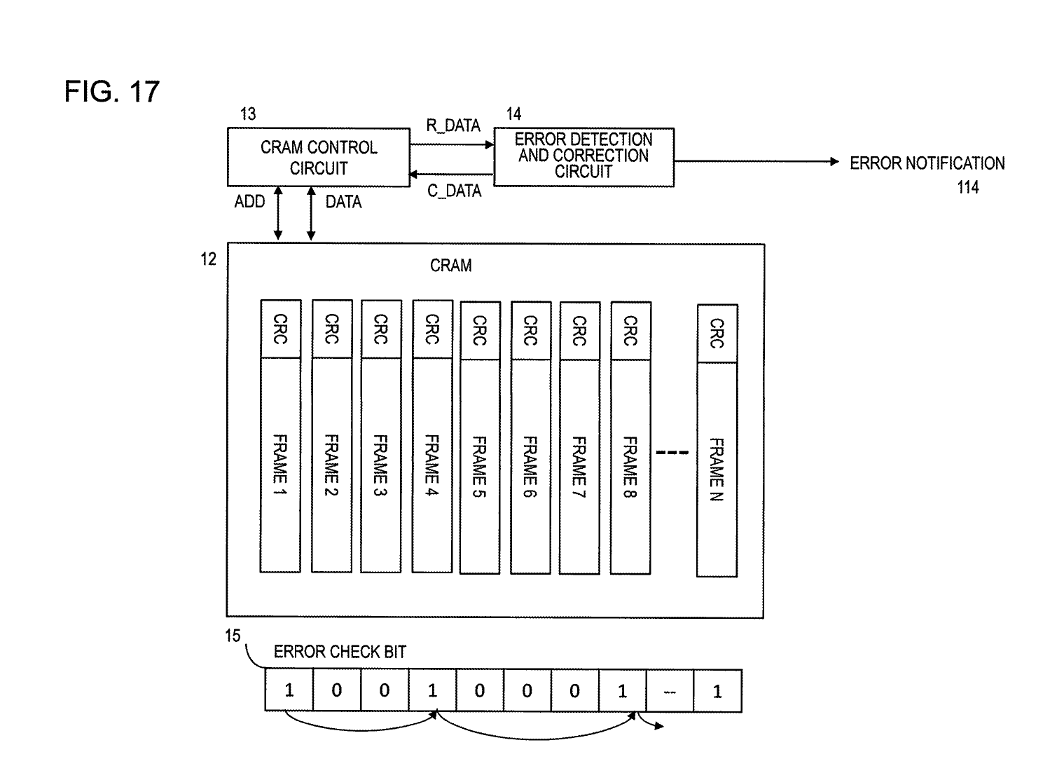

FIG. 17 is a diagram depicting a variation of the first embodiment. In the variation, instead of the arrangement in which the next frame addresses N_Fadd are written to each frame in the configuration memory, an error check bit register 15 having an error check bit indicating whether or not each frame is an error check target is provided in the error detection control circuit 134 such that, when the configuration data is downloaded, error check bits are set in the error check bit register 15. The error detection control circuit 134 references the error check bit register 15 to detect error-check-target frame addresses. Storing the error-check-target frame addresses in the error check bit register 15 eliminates the need to write the next frame addresses into the configuration memory as in the case of FIG. 8.

The error check bit register 15 depicted in FIG. 17 stores error check bits indicating whether or not each frame is an error check target (an error check target is indicated by 1), in association with frame addresses 1 to N. The error detection control circuit 134 in the configuration memory controller 13 determines that the error-check-target frame addresses Fadd are 1, 4, 8, 12, and N (12 is not depicted in FIG. 17) with reference to the error check bit register 15.

### Second Embodiment

In a second embodiment, check-target frame addresses are managed according to the error check priority value because a plurality of circuit blocks corresponding to the configuration data in each frame address may have different error check priority values.

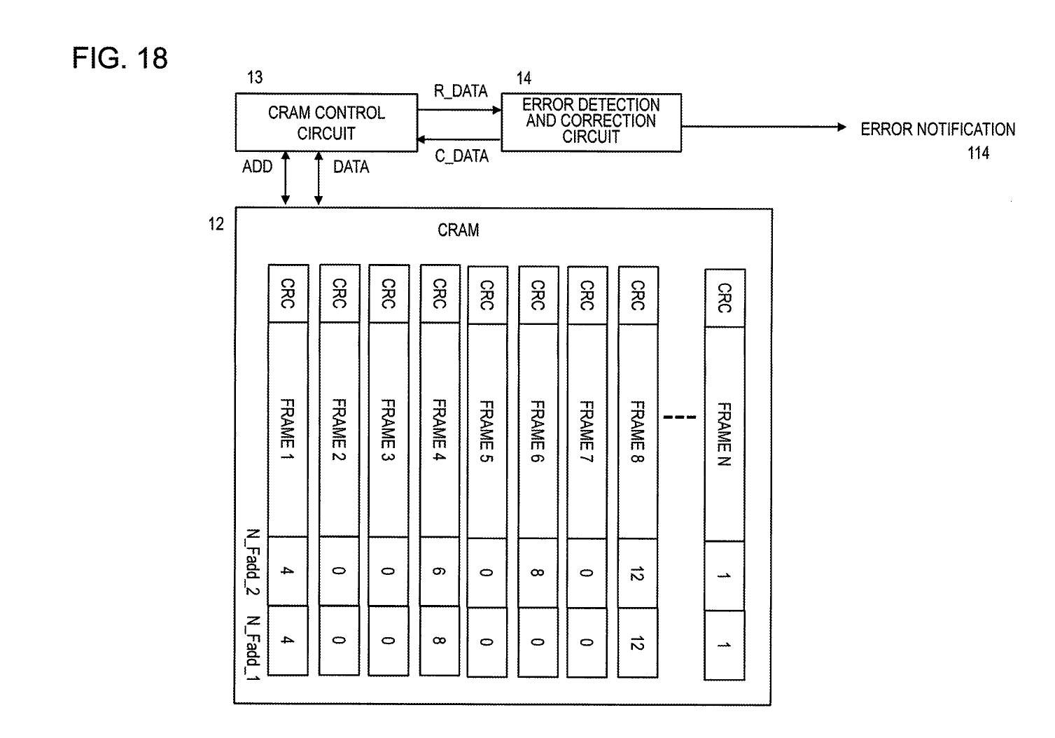

FIG. 18 is a diagram depicting an example of a configuration of a programmable logic circuit device in the second embodiment. In FIG. 18, two types of next frame addresses N_Fadd_1 and N_Fadd_2 are stored in each of the frame addresses in the configuration memory 12. To execute an error check corresponding to an error check priority value of “1”, the CRAM control circuit 13 references the next frame address N_Fadd_1 to read the configuration data. To execute error checks corresponding to priorities (1 and 2) with an error check priority value of “2” or more, the CRAM control circuit 13 references the next frame address N_Fadd_2 to read the configuration data.

The next frame address N_Fadd_1 for an error check priority value of 1 is the same as the next frame address in the example in FIG. 8. On the other hand, for the next frame address N_Fadd_2 for an error check priority value of 2 or more (priorities of 2 and 1), the next frame address N_Fadd_2=6 is added to the frame 6.

Flexible settings other than the setting in FIG. 18 are possible. For example, the error check priority value may be set to only 2 or only 3.

Storing a plurality of types of next frame addresses N_Fadd_1 and N_Fadd_2 as in FIG. 18 enables the following error check. For example, in the normal soft error check, the error detection control circuit 134 in the CRAM control circuit 13 references the first next frame address N_Fadd_1 to sequentially execute an error check on the configuration data. After the self failure detection function detects a failure in the second circuit block, the error detection control circuit 134 references the second next frame address N_Fadd_2 only once to execute an error check.

### Variation of the Second Embodiment

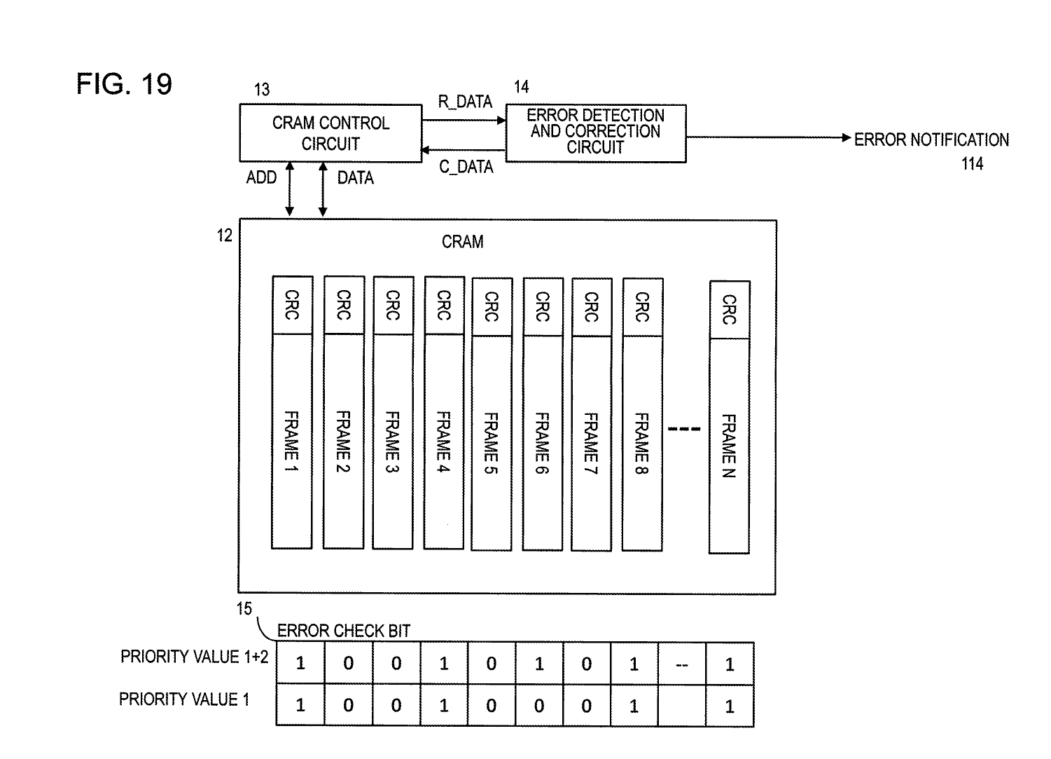

FIG. 19 is a diagram depicting an example of a configuration of a programmable logic circuit device in a variation of the second embodiment. Like FIG. 17, FIG. 19 illustrates an example in which the second embodiment is implemented using the error check bit register.

In FIG. 19, the error check bit register 15 stores an error check bit with an error check priority value of“1” and an error check bit with an error check priority value of “1+2”. The error detection control circuit 134 sets these error check bits in the error check bit register 15 when the configuration data is downloaded.

The error check bit corresponding to a priority value of “1” is the same as the error check bit corresponding to a priority value of “1” in FIG. 17. On the other hand, the error check bit corresponding to a priority value of “1+2” is set to an effective bit “1” in addition to an effective bit of “1” at frame addresses of 1, 4, 8, 12, and N with a priority value of “1”.

As described above, in the present embodiment, the error check period for the configuration data in the configuration memory can be shortened, enabling a reduction in the period of the failure state of the logic circuit. As a result, the mean time to failure of the programmable logic circuit device can be reduced.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A programmable logic circuit device comprising:
a configuration memory that stores configuration data;
a programmable logic circuit in which a logic circuit is configured based on the configuration data stored in the configuration memory;
a control circuit that sequentially and repeatedly reads, from the configuration memory, target configuration data corresponding to an error-check-target circuit in the programmable logic circuit, from among the configuration data in the configuration memory and; and
an error detection circuit that executes an error check on the target configuration data read by the control circuit.

2. The programmable logic circuit device according to claim 1, wherein
the control circuit writes in the configuration memory an address of the target configuration data in addition to the configuration data, and
the control circuit reads the address of the target configuration data from the configuration memory, reads the target configuration data based on the address, and supplies the target configuration data to the error detection circuit.

3. The programmable logic circuit device according to claim 2, wherein
the control circuit writes the configuration data, which are divided, at a plurality of addresses in the configuration memory,
the control circuit writes, in addition to the configuration data being divided a next address, which is an address of the next target configuration data to be checked, to each of the plurality of addresses, and
the control circuit reads the configuration data and the next address at a first address and reads the configuration data at a second address based on the next address.

4. The programmable logic circuit device according to claim 2, wherein
the configuration data stored at the plurality of addresses in the configuration memory are assigned with a plurality of check priority values indicating that the configuration data are the target configuration data,
the control circuit writes the addresses of the target configuration data in the configuration memory in association with the plurality of check priority values respectively, and
the control circuit reads the address of the target configuration data corresponding to a selected check priority value from the configuration memory.

5. The programmable logic circuit device according to claim 1, further comprising:
an error check bit register that stores, in association with the plurality of addresses in the configuration memory respectively, error check bits indicating whether or not the target configuration data are stored at the plurality of addresses in the configuration memory respectively, and
the control circuit sequentially reads the data at addresses where the error check bits in the error check bit register indicate that the target configuration data are stored.

6. The programmable logic circuit device according to claim 5, wherein
the configuration data stored at the plurality of addresses in the configuration memory are assigned with a plurality of check priority values indicating that the configuration data are the target configuration data,
the error check bit register stores the error check bits in association with the plurality of check priority values respectively, and
the control circuit sequentially reads the addresses where the error check bit that is in the error check bit register and that corresponds to a selected check priority value indicates that the target configuration data are stored.

7. The programmable logic circuit device according to claim 1, wherein the error detection circuit has an error correction circuit that corrects the configuration data in which an error is detected, and
the control circuit writes corrected configuration data resulting from correction by the error correction circuit in the configuration memory, and when the error correction circuit fails to correct the configuration data, downloads the configuration data in a second configuration memory into the configuration memory.

8. A method of detecting error in a programmable logic circuit device which includes a configuration memory that stores configuration data, a programmable logic circuit in which a logic circuit is configured based on the configuration data stored in the configuration memory, and an error detection circuit that executes an error check on the target configuration data read by the control circuit, the method comprising:
sequentially and repeatedly reading, from the configuration memory, target configuration data corresponding to an error-check-target circuit in the programmable logic circuit, from among the configuration data in the configuration memory and; and
error checking, by the error detection circuit, on the target configuration data read by the control circuit.

9. The method of detecting error according to claim 8, further comprising:
writing in the configuration memory an address of the target configuration data in addition to the configuration data, and
reading the address of the target configuration data from the configuration memory, reading the target configuration data based on the address, and supplying the target configuration data to the error detection circuit.
